(19) United States
(12) Patent Application Publication
(10) Pub. No.: US 2002/0155660 A1
(43) Pub. Date: Oct. 24, 2002

(54) Method for producing a microelectronic structure

(76) Inventors: Gerhard Beitel, Muhldorf/Inn (DE); Wolfgang Hoenlein, Unterhaching (DE); Reinhard Stengl, Stadtbergen (DE); Elke Fritsch, Munich (DE); Siegfried Schwarzl, Neubiberg (DE); Hermann Wendt, Grasbrunn (DE)

Correspondence Address: Craig Gregersen, Briggs and Morgan, P.A., W2200 First National Bank Building, St. Paul, MN, 55101, US

(21) Appl. No.: 09/948,010

(22) Filed: Sep. 5, 2001

(30) Foreign Application Priority Data
Mar. 10, 2000 (DE) PCT/DE00/00786

(51) Int. Cl. H01L 21/00; H01L 21/8242

(52) U.S. Cl. 438/240; 438/3

(57) ABSTRACT

A method for producing a microelectronic structure is suggested in which a layer structure (30) which partially covers a substrate (5) and which comprises at least one first conductive layer (15,20) which reaches to a side wall (35) of the layer structure (30), is covered with a second conductive layer (45). The second conductive layer (45) is then subsequently back-etched to as great an extent as possible with an etching process with physical delamination, wherein delaminated material deposits on the side wall (35) of the layer structure (30). On the side wall (35) the delaminated material forms a protection layer (60) by means of which the first conductive layer (15,20) is to be protected from attack by oxygen to the furthest extent possible.

The invention is in the field of semiconductor technology and relates to a method for producing a microelectronic structure, in particular a method for the production of semiconductor memory elements.

In the production of semiconductor memory elements, which for example represent a microelectronic structure, materials with a high dielectric constant or with ferroelectric properties are increasingly used as the capacitor dielectric. In general, such semiconductor memory elements comprise a plurality of memory cells including at least one selection transistor and a storage capacitor. The storage capacitor consists of the capacitor dielectric located between two electrodes. A suitable capacitor dielectric with sufficiently high dielectric constant is for example barium-strontium-titanate (BST). In its deposition or a necessary subsequent treatment, this material however requires an oxidizing atmosphere which can lead to an oxidation of the electrodes. In an undesirable case, the electrodes are oxidized and thereby rendered useless. For this reason, oxidation-resistant materials, for example platinum, have been suggested as electrode materials. At higher temperatures, however, platinum which is directly contacted with silicon tends toward a silization which worsens the electrical conductivity of the electrodes. For this reason, a diffusion barrier is normally positioned between the platinum electrode and a contact hole filled with silicon, wherein the diffusion barrier is intended to prevent a diffusion of platinum or silicon.

In addition, oxygen can diffuse through platinum relatively easily and oxidize layers located under the platinum layer, for example the platinum or silicon diffusion barrier. For this reason a further diffusion barrier is required which, in particular, prevents oxygen diffusion.

Frequently used barrier systems consist of a layer combination made of a titanium and a titanium nitride layer or of a tantalum and a tantalum nitride layer. The platinum layer is subsequently applied to this barrier system and is etched along with the barrier system. In this way a normally planar layer stack is generated with exposed barrier layers at the edges of the layer stack. It is in particular these edge regions which are subjected to the oxygen-containing atmosphere in the subsequent deposition of the capacitor dielectric and can at least partially oxidize. Furthermore, it has become clear that, in the deposition of the capacitor dielectric by means of a CVD (Chemical Vapor Deposition) process, the layer thickness of the deposited capacitor dielectric can depend on the respective base layer (platinum or barrier). However, in the application of a potential to both of the electrodes of the storage capacitor, a varying layer thickness of the capacitor dielectric leads to field strengths of differing magnitude, which can lead to early dropouts of the capacitor dielectric. Furthermore the local oxidative disintegration of the barrier layer in the edge regions of the layer stack can lead to a volume increase and thereby to high mechanical stresses or to a worsening of the electrical contact to the substrate located beneath.

According to EP 0 739 030 A2, in order to protect the barrier layer in particular in the edge regions of the layer stack, either lateral passivating edge webs made of an insulating material are used or the barrier layer is completely covered with a conductive oxygen-resistant layer. A further possibility is to bury the barrier layer. The polishing step required for this purpose is, however, relatively costly.

It is therefore a goal of the present invention to provide a method by which the edge regions of the barrier layer are protected from oxidation to the furthest possible extent.

According to the invention, this goal is achieved by methods for the production of a microelectronic structure with the following steps:

a layer structure arranged on a substrate is provided which partially covers the substrate, and which comprises at least one first conductive layer reaching to a side wall of the layer structure;

a second conductive layer is applied onto the layer structure and onto the substrate; and

the second conductive layer is subsequently at least partially delaminated from the substrate using an etching process with physical delamination, so that delaminated material at least partially deposits on the side wall of the layer structure.

According to the invention, a second conductive layer is applied onto the layer structure at least partially covering the substrate as well onto the substrate itself. Here, it is not necessary that the second conductive layer conformally covers the layer structure and the substrate. Rather, the second conductive layer should sufficiently cover at least the exposed substrate with a certain layer thickness. The side wall of the layer structure to be protected and, in particular, the first conductive layer reaching to the side wall are sequentially covered with material from the second conductive layer by means of a suitably chosen delamination and deposition process. This takes place in particular using an etching process with physical delamination by means of which the material is delaminated from the second conductive layer and can subsequently redeposit on the surface of the layer structure and the substrate. Such transposition processes are achieved for example by means of argon sputtering.

In this transposition of material, detached material precipitates on the side wall of the layer structure and covers the latter. The height of the precipitation depends, among other things, on the inclination of the side wall, the energy dose of the impinging argon ions as well as on the angle distribution of the ejected atoms.

By the delamination of the second conductive layer, the second conductive layer is removed from the upper side of the layer structure and from the exposed substrate to as great an extent as possible. Due to the prevailing geometric conditions, the delamination of material from the side walls of the layer structure takes place markedly slower than from the upper side of the layer structure and from the exposed substrate. On the other hand, delaminated material on the total surface of the layer structure and of the substrate can redeposit, wherein this however takes place in a cosine-shaped angle distribution relative to the impinging sputter atoms. The simultaneously occurring delamination and deposition processes lead however to a net delamination of the second conductive layer from, in particular, the upper side of the layer structure and from the exposed substrate, and to a net application of delaminated material, in particular on the side walls of the layer structure. One can therefore correctly speak of a transposition of material from essentially horizontal surfaces to essentially vertical surfaces, wherein the essentially vertical surfaces lie approximately parallel or at an acute angle to the impinging sputter atoms. The sputter atoms are formed by the etching substances, for example argon, used in the etching process.

Preferably, the second conductive layer should have a sufficient thickness so that a sufficient amount of material is available for redeposition onto the respective side walls or the side wall of the layer structure. The aim is to completely cover at least the first conductive layer with redeposited material from the second conductive layer.

Preferably, at least the second conductive layer is completely removed from the substrate by means of the etching process. Here, it is irrelevant whether the second conductive layer is also completely removed from or partially remains on the upper side of the layer stack.

In general, the first conductive layer represents a barrier layer and/or an adhesion layer. A third conductive layer can be located on this barrier layer and/or adhesion layer, wherein the third conductive layer is in particular used as the electrode material in semiconductor memory elements. This can be either a conductive metal layer or a conductive metal oxide layer. In particular, the metal layer can be composed of platinum, ruthenium, iridium, osmium, rhodium, rhenium or palladium and the metal oxide layer can be composed of in particular ruthenium oxide, iridium oxide, rhenium oxide, osmium oxide, strontium-ruthenium oxide or rhodium oxide. Preferably the layer structure consists of the first conductive layer resting below and the third conductive layer located on the upper side of the first conductive layer.

The second conductive layer, which preferably consists of platinum, is applied to this layer structure and is distributed with the etching process with physical delamination on the surface of the substrate or the layer structure, so that a contiguous platinum layer is formed, in particular, on the side wall of the layer structure. This platinum layer is intended to cover, in particular, the edge regions of the first conductive layer and to protect these, in particular, from attack by oxygen in subsequent process steps.

To the extent that the second and the third conductive layer are composed of the same material, following the back-etching of the second conductive layer the layer structure comprises a surface which is composed entirely of one material. This has the advantageous effect on characteristics of layers which are to subsequently be applied to the layer structure. The second and third conductive layer are preferably composed of a precious metal, in particular platinum.

The etching process should further remove the second conductive layer as completely as possible from the substrate so that neighboring layer structures are not electrically connected by the second conductive layer.

Following production of the side wall protective layer, a dielectric metal oxide-containing layer is deposited in as conformal a manner as possible. For the dielectric metal oxide-containing layer, which in particular represents in a semiconductor memory element the high—□—dielectric or the ferroelectric capacitor dielectric, in particular metal oxides of the general form ABOₓ and DOₓ are used, wherein A stands in particular for at least one metal from the group strontium (Sr), bismuth (Bi), niobium (Nb), lead (Pb), zirconium (Zr), lanthanum (La), lithium (Li), potassium (K), calcium (Ca) and barium (Ba), B stands in particular for at least one metal of the group titanium (Ti), niobium (Nb), ruthenium (Ru), magnesium (Mg), manganese (Mn), zirconium (Zr) or tantalum (Ta), D stands for titanium (Ti) or tantalum (Ta) and O stands for oxygen. X can be between 2 and 12. Depending on composition, these metal oxides have dielectric or ferroelectric properties, wherein the intended high dielectric properties (□>20) or the high residual polarization with ferroelectrics might, as the case may be, only be reached after a high temperature step to crystallize the metal oxides. These materials exist under certain circumstances in polycrystalline form, wherein perovskite-like crystal structures, mixed crystals, layer-shaped crystal structures or superlattices can often be observed. Fundamentally, all perovskite-like metal oxides of the general form ABOₓ are suitable for formation of the dielectric metal oxide-containing layer. Dielectric materials with high □(□>50) as well as materials with ferroelectric properties are for example barium-strontium-titanate (BST, Ba₁₋ₓSrₓTiO₃), niobium doped strontium-bismuth-tantalate (STBN, SrₓBi_{y}(Ta_{z}Nb_{1-z}) O₃, strontium-titanate (STO, SrTiO₃), strontium-bismuth-tantalate (SBT, SrₓBi_{y}Ta₂O₉), bismuth-titanate (BTO, Bi₄Ti₃O₁₂), lead-zirconate-titanate (PZT, Pb(ZrₓTi₁₋ₓ)O₃), strontium-niobate (SNO, Sr₂Nb₂O₇), potassium-titanate-niobate (KTN) as well as lead-lanthanum-titanate (PLTO, (Pb,La)TiO₃). Tantalum oxide (Ta₂O₅) can in addition be used as a high □ dielectric. In the following, the term dielectric should be understood as a dielectric, paraelectric or ferroelectric layer, so that the dielectric metal oxide-containing layer can have dielectric, paraelectric or ferroelectric properties.

In addition to the protection of the side regions of the first conductive layer, the microelectronic structure produced by means of the method according to the invention additionally also comprises a uniform base layer for the deposition of the dielectric metal oxide-containing layer. This is achieved in particular in that not only the third conductive layer but also the second conductive layer are composed of platinum and in that not only the upper side of the layer structure but also its side walls are covered with a platinum layer. The surface of the layer structure, which is made of the same material, enables a relatively uniform edge covering of the layer structure with the dielectric metal oxide-containing layer, wherein in particular local high electric field strengths can be avoided. In addition, the protective layer of platinum formed on the side wall of the layer structure protects the first conductive layer from oxidation to the greatest extent possible.

In the following the invention is described in reference to an embodiment and is schematically represented in figures.

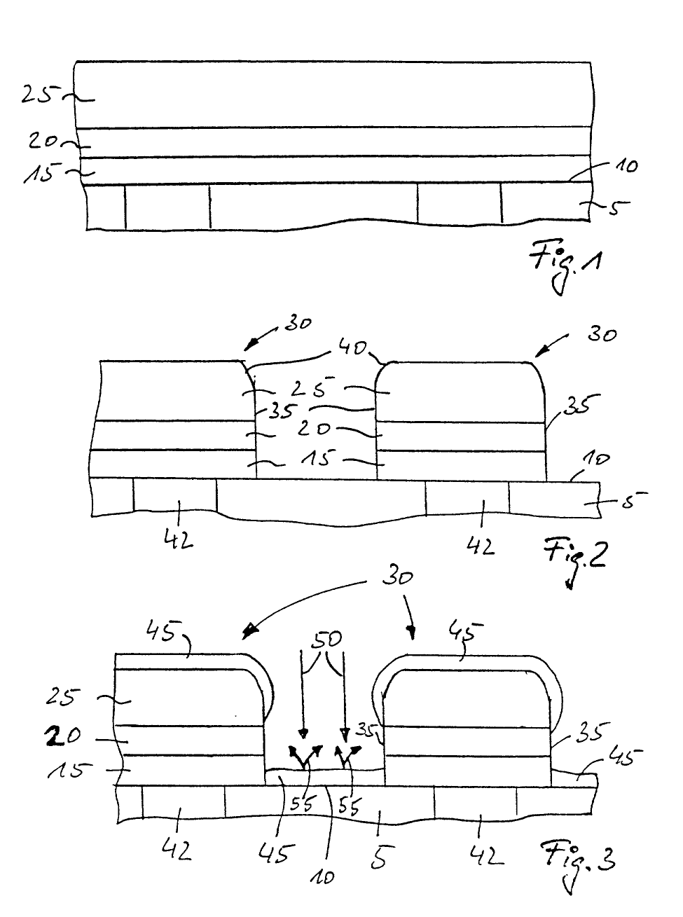

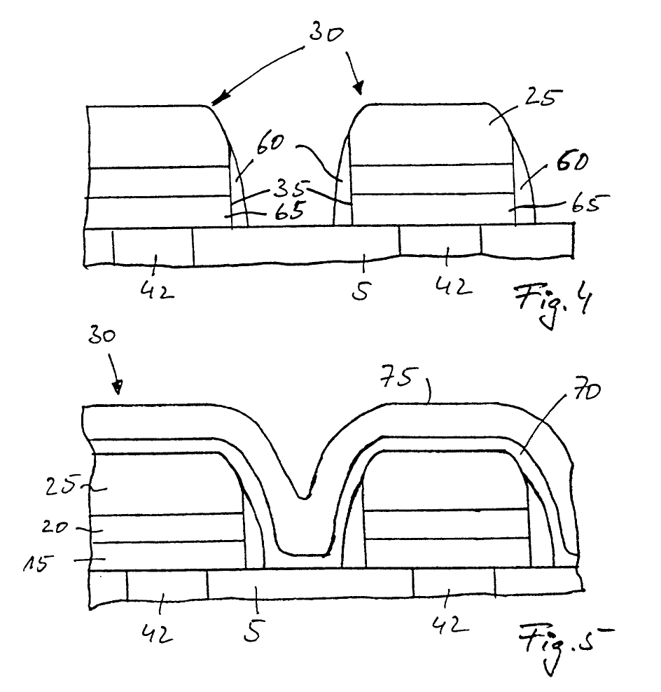

FIGS. 1 to 5 show various process steps in the production of a microelectronic structure.

FIG. 1 shows a substrate 5 on the surface 10 of which a titanium layer 15, a titanium nitride layer 20 and a platinum layer 25 sit in the form of a layer stack. The titanium layer 15 can also optionally be composed of tantalum and the titanium nitride layer 20 can also optionally be composed of tantalum nitride. Subsequently the three layers 15, 20 and 25 are etched together, wherein layer structures 30 which are separate from one another remain the surface 10 of the base substrate. These layer structures 30 each include the titanium layer 15 and titanium layer 20 located in the lower region and the platinum layer 25 located in the upper region. In this embodiment the platinum layer 25 represents the third conductive layer whereas the titanium layer 15 and the titanium nitride layer 20 together form the first conductive layer. Between the platinum layer 25 and the titanium nitride layer 20 can be optionally arranged a further layer, in particular an oxygen diffusion barrier, which can also be counted as part of the first conductive layer.

The layer structures 30 each comprise at least one side wall 35, which in the present case are arranged nearly perpendicular to the surface 10 of the substrate 5. The side wall 35 can however also be inclined. The incline depends in particular on the etching process used to structure the platinum layer 25, the titanium layer 15 and the titanium nitride layer 20. This is suggestively represented by rounded off comers 40 of the platinum layer 25. In as far as the layer structure 30 is formed to be cylindrical, it comprises a single side wall 35 which completely encircles the layer structure. Under each layer structure 30 is further located a contact hole 42 which is filled with polysilicon and which penetrates the substrate 5 and, for example, leads to a selection transistor (here not further shown).

Subsequently a further platinum layer 45, which represents here the second conductive layer, is applied onto the substrate 5 and the layer structure 30. Here, it is not necessary that the side wall 35 of the layer structure 30 is covered with the further platinum layer 45. In this way, nonconformal processes, for example sputtering or evaporation, can be used to apply the platinum layer 45. Subsequently the further platinum layer 45 is back-etched by a sputter etch process. In this etch process, gas mixtures of argon and further additives, for example chlorine and oxygen, are normally used. The additives effect, in particular, a uniform back-etching of the platinum layer 45, wherein relatively smooth surfaces can be generated. The actual delamination of the further platinum layer 45 takes place during the sputter etch process by bombardment of the further platinum layer 45 with directed argon ions, in other words the argon ions are accelerated by means of an electrical field and impinge on the further platinum layer 45 with relatively high velocity. The angle at which the argon ions impinge upon the further platinum layer 45 can be freely chosen, but should be set such that the further platinum layer 45 located between two layer structures can be removed from the surface 10 of the substrate 5 as completely as possible. This is necessary on the one hand for the complete electric insulation of neighboring layer structures 30 and on the other hand in order to cover the side wall 35 of each layer structure 30 as completely as possible. The impinging argon ions are represented by arrows 50.

In contrast to the directed argon ions 50, the platinum atoms ejected from the further platinum layer 45 have an angular distribution which essentially corresponds to a cosine distribution. In this way, delaminated platinum atoms reach the side wall or side walls 35 of the layer structures 30 and can deposit there. The freed platinum atoms are indicated by arrows 55.

By the back-etching of the further platinum layer 45, metallic protection layers 60 are formed in the shape of lateral edge webs on the side wall 35 of the layer structure 30. These are composed almost entirely of delaminated material from the further platinum layer 45 which itself was almost completely removed from the surface 10 of the substrate 5. It is important to note here that the layer structures 30 are now no longer electrically connected to one another via the platinum layer 45. By means of the metallic protection layer 60 composed of platinum, which completely covers the side wall 35 and reaches to the platinum layer 25, the layer structure 30 is completely coated by a platinum layer. In this way a surface composed of a single material is provided for the subsequent deposition of the dielectric metal oxide-containing layer. In addition, the metallic protection layer 60 protects the titanium layer 15 and the titanium layer 20 in their edge regions 65, in other words in the region of the side wall 35 of the layer structure 30. A further advantage of the microelectronic structure produced by this method is to be seen in that the applied metallic protection layer 60 covers and easily compensates sharp edges of any layer structure which might be present. In this way, topologies which are difficult to cover are smoothed, by which steady or continuously progressing height transitions are created, upon which the dielectric metal oxide-containing layer which is to be subsequently applied can grow uniformly and free of stress. In addition, the metallic protection layer 60 has a slight inclination which also contributes to an improved deposition of the dielectric metal oxide-containing layer. The structure described is depicted in FIG. 4.

According to FIG. 5, a dielectric metal oxide-containing layer 70, for example a BST layer, is finally applied conformally onto the entire surface of the layer structure 30 and the substrate 5. This preferentially takes place by means of a CVD process, wherein the layer thickness, at least in the region of the metallic protection layer 60 and the platinum layer 25, is almost constant due to material identity. An upper electrode layer 75 made of platinum is finally applied as conformally as possible over the entire surface of the dielectric metal oxide-containing layer 70. It may still be necessary to subject the dielectric metal oxide-containing layer 70 to a crystallization process by means of a high temperature step in the presence of oxygen, through which the intended dielectric properties, in other words either a high relative dielectric constant or a residual polarization are to be improved.

The method according to the invention is in particular used in the production of semiconductor memory elements, in which a plurality of storage capacitors are located on an insulating substrate 5, wherein the storage capacitors are built up as a stack. Here, the first, second and third conductive layer represent the lower electrode including the necessary barriers, which are covered by a capacitor dielectric (dielectric metal oxide-containing layer) and a further upper electrode layer.

1. Method for the production of a microelectronic structure, with the following steps:
a layer structure (30) arranged on a substrate (5) is provided which partially covers the substrate (5), and which comprises at least one first conductive layer (15,20) reaching to a side wall (35) of the layer structure (30);
a second conductive layer (45) is applied onto the layer structure (30) and onto the substrate (5); and
the second conductive layer (45) is subsequently at least partially delaminated from the substrate (5) using an etching process with physical delamination, so that delaminated material at least partially deposits on the side wall (35) of the layer structure (30).

2. Method according to claim 1,
characterized in that
a contiguous protection layer (60) completely covering at least the first conductive layer (15,20) is formed by the material which is delaminated and deposited on the side wall (35).

3. Method according to claim 1 or 2,
characterized in that
the layer structure (30) comprises a third conductive layer (25) which covers the first conductive layer (15,20).

4. Method according to claim 3,
characterized in that
the first conductive layer (15,20) is a barrier layer and/or an adhesion layer.

5. Method according to any of claims 1 to 4,
characterized in that
the barrier layer and/or adhesion layer (15,20) is composed of a titanium nitride/titanium combination or of a tantalum nitride/tantalum combination.

6. Method according to and of claims 1 to 5,
characterized in that
the third conductive layer (25) is a metal layer (25).

7. Method according to claim 6,
characterized in that
the metal layer (25) contains platinum, ruthenium, iridium, osmium, rhodium, rhenium, palladium or an alloy of the previously named metals.

8. Method according to any of claims 1 to 5,
characterized in that
the third conductive layer (25) is a metal oxide layer (25).

9. Method according to claim 8,
characterized in that
the metal oxide layer (25) contains ruthenium oxide, iridium oxide, rhenium oxide, osmium oxide, strontium-ruthenium oxide or rhodium oxide.

10. Method according to one of the previous claims,
characterized in that
the second conductive layer (45) is composed of platinum.

11. Method according to one of the previous claims,
characterized in that
a dielectric metal oxide-containing layer (70) is applied onto the layer structure (30).

12. Method according to claim 11,
characterized in that
the dielectric metal oxide-containing layer (70) contains a material of the general form ABOₓ and DOₓ, wherein A stands for at least one metal from the group strontium (Sr), bismuth (Bi), niobium (Nb), lead (Pb), zirconium (Zr), lanthanum (La), lithium (Li), potassium (K), calcium (Ca) and barium (Ba), B stands for at least one metal of the group titanium (Ti), niobium (Nb), ruthenium (Ru), magnesium (Mg), manganese (Mn), zirconium (Zr) or tantalum (Ta), D stands for titanium (Ti) or tantalum (Ta) and O stands for oxygen.
